(19) United States
(12) Patent Application Publication
(10) Pub. No.: US 2025/0221286 A1
(43) Pub. Date: Jul. 3, 2025

(54) DISPLAY DEVICE

(71) Applicant: LG Display Co., Ltd., Seoul (KR)

(72) Inventors: JaeMin SHIM, Paju-si (KR); Mihee UHM, Paju-si (KR); Seoil JEON, Paju-si (KR); GeunGi LEE, Paju-si (KR); WooSang KIM, Paju-si (KR)

(73) Assignee: LG Display Co., Ltd., Seoul (KR)

(21) Appl. No.: 18/968,244

(22) Filed: Dec. 4, 2024

(30) Foreign Application Priority Data
Dec. 27, 2023 (KR) 10-2023-0192305

(51) Int. Cl. H10K 59/80; H10K 59/38

(52) U.S. Cl. CPC H10K 59/8792; H10K 59/872; H10K 59/8722; H10K 59/38

(57) ABSTRACT

A display device can include a first substrate having a first grinding surface at an edge thereof, a second substrate facing the first substrate and having a second grinding surface at an edge thereof, a plurality of pixels disposed on one surface of the first substrate, a display area including the plurality of pixels, a non-display area disposed outside the display area, a dam disposed between the first substrate and the second substrate in the non-display, and a first pattern disposed outside the dam.

### CROSS-REFERENCE TO RELATED APPLICATIONS

This application claims the benefit of and priority to Korean Patent Application No. 10-2023-0192305, filed in the Republic of Korea on Dec. 27, 2023, the entire contents of which are expressly incorporated herein by reference for all purposes.

### BACKGROUND

### 1. Technical Field

The present disclosure relates to a display device.

### 2. Discussion of the Related Art

With advancement in information-oriented societies, demands for display devices that display an image have increased in various forms. Various types of display devices such as a liquid crystal display LCD device, a plasma display panel PDP device, a Quantum dot Light Emitting Display QLED, and an organic light emitting display OLED device have been widely utilized.

The display device includes two substrates, and a plurality of light emitting devices are disposed between the two substrates to display images. In the display device, a curved surface or an inclined surface can be provided at an edge portion by grinding the edge portion of each of the substrates through a grinding process using a grinder. In the grinding process, after grinding the edge portion of each of substrates, a grinding amount can be measured by a vision camera, and a defect of the product can be determined based on the result value.

The description of the related art should not be assumed to be prior art merely because it is mentioned in or associated with this section. The description of the related art includes information that describes one or more aspects of the subject technology, and the description in this section does not limit the invention.

### SUMMARY

One or more aspects of the present disclosure are directed to providing a display device, which substantially obviates one or more problems due to limitations and disadvantages of the related art.

One or more aspects of the present disclosure are directed to providing a display device capable of improving a boundary recognition rate of grinding surface when measuring a grinding amount using a vision camera.

One or more aspects of the present disclosure are directed to providing a display device, which is capable of realizing Environment/Social/Governance (ESG) by reducing the generation of greenhouse gases due to the manufacturing process.

Other aspects, features and advantages of the present disclosure are set forth in the present disclosure and will also be apparent from the present disclosure or may be learned by practice of the inventive concepts provided herein. Other aspects, features and advantages of the present disclosure may be realized and attained by the descriptions provided in the present disclosure, including the claims and the drawings.

To achieve these and other advantages and aspects of the present disclosure, as embodied and broadly described herein, in one or more aspects, there is provided a display device including a first substrate having a first grinding surface at an edge thereof, a second substrate facing the first substrate and having a second grinding surface at an edge thereof, a plurality of pixels disposed on one surface of the first substrate, a display area including the plurality of pixels, a non-display area disposed outside the display area, a dam disposed between the first substrate and the second substrate in the non-display area, and a first pattern disposed outside the dam.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with example embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and example embodiments of the present disclosure, and together with the description serve to explain principles and examples of the disclosure. In the drawings:

FIG. 1 is a perspective view schematically illustrating a display device according to one or more example embodiments of the present disclosure;

FIG. 2 is a plan view schematically illustrating a display panel according to one or more example embodiments of the present disclosure;

FIG. 3 is a plan view illustrating an example of sub-pixel disposed in the display panel according to one or more example embodiments of the present disclosure;

FIG. 4 is a plan view illustrating a first pattern and a second pattern disposed in the display panel according to one or more example embodiments of the present disclosure;

FIG. 5 is a cross-sectional view illustrating one example taken along line I-I′ illustrated in FIG. 4;

FIG. 6 is a cross-sectional view illustrating an example taken along line II-II′ illustrated in FIG. 4;

FIG. 7 is a cross-sectional view illustrating an example taken along line III-III′ illustrated in FIG. 4;

FIG. 8 illustrates an example of a bottom surface image acquired through a vision camera; and

FIG. 9 illustrates an example of a top surface image acquired through a vision camera.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art. Furthermore, the present disclosure is only defined by scopes of claims.

A shape, a size, a ratio, an angle, and a number disclosed in the drawings for describing embodiments of the present disclosure are merely an example, and thus the present disclosure is not limited to the illustrated details. Like reference numerals refer to like elements throughout. In the following description, when the detailed description of the relevant known technology is determined to unnecessarily obscure the important point of the present disclosure, the detailed description will be omitted. In a case where “comprise”, “have”, and “include” described in the present disclosure are used, another part can be added unless “only” is used. The terms of a singular form can include plural forms unless referred to the contrary.

In construing an element, the element is construed as including an error range although there is no explicit description.

In describing a positional relationship, for example, when a position relation between two parts is described as “on”, “over”, “under”, and “next”, one or more other parts can be disposed between the two parts unless “just” or “direct” is used.

In describing a temporal relationship, for example, when a temporal precedence relationship is described such as “after”, “following”, “next”, “before”, etc., it can include cases that are not consecutive unless “immediately” or “directly” are used.

It will be understood that, although the terms “first”, “second”, etc. can be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure can be partially or totally coupled to or combined with each other, and can be variously inter-operated and driven technically. The embodiments of the present disclosure can be carried out independently from each other or can be carried out together with a co-dependent relationship.

Hereinafter, with reference to the accompanying drawings, one example of a display device according to the present disclosure is described. In assigning reference numerals to the components in each drawing, the same component can have the same numeral as far as possible, even if it is shown in different drawings. In addition, when the detailed description of the relevant known technology is determined to unnecessarily obscure the important point of the present disclosure, the detailed description will be omitted.

Hereinafter, with reference to the accompanying drawings, one or more example embodiments of the present disclosure will be described.

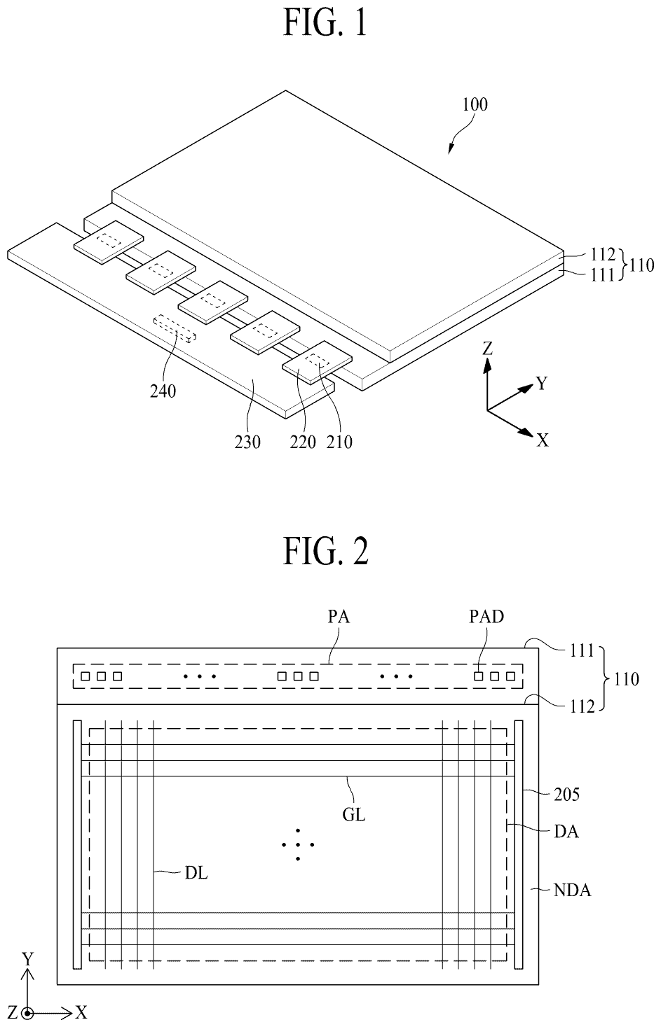

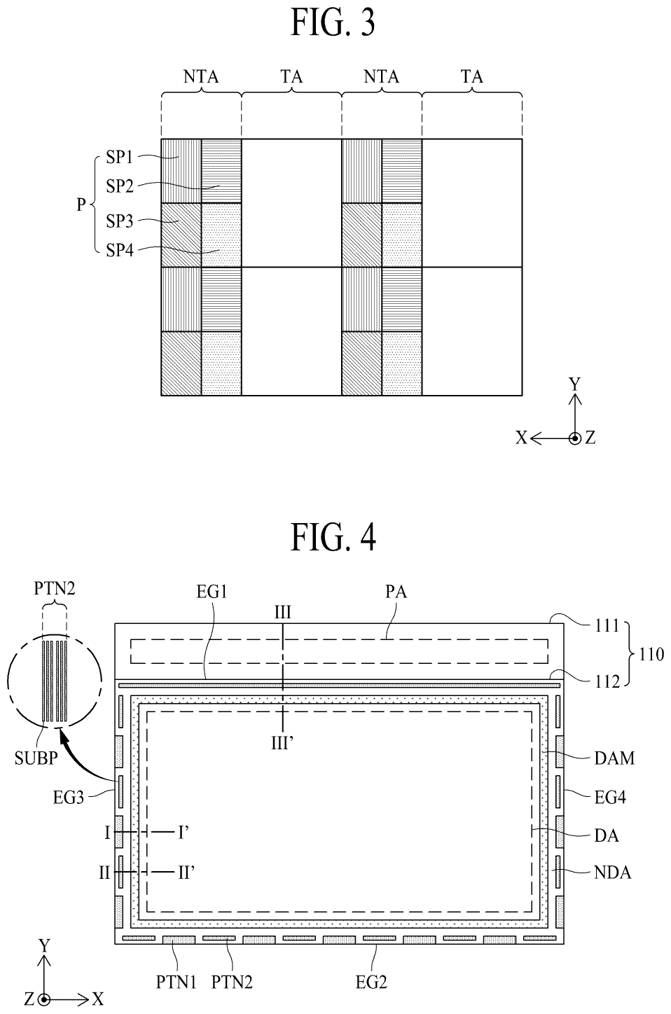

FIG. 1 is a perspective view schematically illustrating a display device according to one or more example embodiments of the present disclosure and FIG. 2 is a plan view schematically illustrating a display panel according to one or more example embodiments of the present disclosure. FIG. 3 is a plan view illustrating an example of sub-pixel disposed in the display panel according to one or more example embodiments of the present disclosure.

Hereinafter, an X axis represents a direction parallel to a gate line, a Y axis represents a direction parallel to a data line, and a Z axis represents a height direction of a display device 100. However, other variations are possible.

An example where the display device 100 according to one or more example embodiments of the present disclosure is implemented as an organic light emitting display apparatus in which light emitting elements are implemented using organic light emitting diodes (OLED) will be mainly described, but the display device 100 can be implemented as a liquid crystal display LCD apparatus, a plasma display panel PDP, a quantum dot light emitting display QLED apparatus, or an electrophoresis display apparatus.

Referring to FIGS. 1 to 3, the display device 100 according to one or more example embodiments of the present disclosure can include a display panel 110, a source driver integrated circuit (hereinafter, referred to as “IC”) 210, a flexible film 220, a circuit board 230, and a timing controller 240.

The display panel 110 includes a first substrate 111 and a second substrate 112 facing each other. The first substrate 111 and the second substrate 112 can be a glass substrate. The first substrate 111 and the second substrate 112 can be formed of other suitable material, such as a transparent material. For example, the first substrate 111 and the second substrate 112 can further include transparent plastic, or a flexible polymer film. For example, the flexible polymer film can be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto. Hereinafter, as one example, the first substrate 111 is expressed as a first glass substrate and the second substrate 112 is expressed as a second glass substrate. For example, the size of the first substrate 111 can be larger than the size of the second substrate 112.

The display panel 110 can be divided into a display area DA and a non-display area NDA. The display area DA includes a plurality of pixels P and displays images. The non-display area NDA does not display the images. The non-display area NDA can refer to an area outside of the display area DA. The non-display area NDA can be also referred to as an edge area or a bezel area.

Data lines DL, gate lines GL, and pixels P can be disposed in the display area DA, and a pad area PA in which pads PAD are disposed and at least one gate driver 205 can be disposed in the non-display area NDA.

The data lines DL can extend in a first direction (e.g., in a Y axis direction) and can intersect the gate lines GL in the display area DA. The gate lines GL can extend in a second direction (e.g., in a X axis direction) in the display area DA.

As illustrated in FIG. 3, the display area DA can include a transmissive area TA and a non-transmissive area NTA. The transmissive area is an area in which most of the light incident from the outside is transmitted and the non-transmissive area is an area in which most of the light incident from the outside is not transmitted. For example, the transmissive area TA can be an area having a light transmittance greater than α%, and the non-transmissive area NTA can be an area having a light transmittance less than β%. In this example, a can be a value greater than β, and each of α and β can be a positive number. The display device 100 can allow viewing of an object or background scenes that are located at a rear surface of the display device 100 due to the transmissive area TA of the display panel 110.

The non-transmissive area NTA includes a plurality of pixels P to emit predetermined light to display images. Each of plurality of pixels P can comprise a plurality of sub-pixels, such as the sub-pixels SP1, SP2, SP3, and SP4, without being limited thereto. Each of the sub-pixels SP1, SP2, SP3, and SP4 can be any one of a first sub-pixel SP1 emitting red light, a second sub-pixel SP2 emitting green light, a third sub-pixel SP3 emitting blue light, and a fourth sub-pixel SP4 emitting white light, but is not limited thereto. The sub-pixels emitting light of other colors (such as cyan, magenta, or yellow, etc.) are also possible. The pixel P can include two or more sub-pixels, such as sub-pixels SP1, SP2, SP3, and SP4, as shown in FIG. 3, without being limited thereto. For example, the pixel P can include a first sub-pixel SP1, a second sub-pixel SP2, a third sub-pixel SP3, and a fourth sub-pixel SP4 as illustrated in FIG. 3. Also, the arrangement order of the sub-pixels SP1, SP2, SP3, and SP4 can be variously changed.

A plurality of pads can be disposed in the pad area PA. Since the size of the first substrate 111 is larger than the size of the second substrate 112, a portion of the first substrate 111 can be exposed and not covered by the second substrate 112. The pads such as power pads or data pads, etc., can be disposed in the portion of the first substrate 111 that is exposed and not covered by the second substrate 112.

The gate driver 205 can be a circuit for driving a plurality of gate lines GL. The gate driver 205 is connected to the gate line to supply a gate signal. The gate driver 205 can be formed in a gate driver in panel GIP type in the non-display area NDA outside of one side or both sides of the display area DA. Alternatively, the gate driver 205 can be fabricated as a driving chip, mounted on a flexible film, and attached to the non-display area NDA outside of one side or both sides of the display area DA in tape automated bonding TAB type.

The source driver IC 210 receives a digital video data and a source control signal from the timing controller 240. The source drive IC 210 converts the digital video data into analog data voltages according to the source control signal and supplies them to the data lines. If the source driver IC 210 is fabricated as a driving chip, it can be mounted on the flexible film 220 in a chip on film COF type or a chip on plastic COP type.

The flexible film 220 can include lines connecting the pads to the source driver IC 210 and lines connecting the pads to the lines of the circuit board 230. The flexible film 220 can be attached on the pads using an anisotropic conducting film, thereby connecting the pads and the lines of the flexible film 220.

The circuit board 230 can be attached to the flexible films 220. The circuit board 230 can have a plurality of circuits implemented with driving chips mounted thereon. For example, the timing controller 240 can be mounted on the circuit board 230. The circuit board 230 can be a printed circuit board or a flexible printed circuit board.

The timing controller 240 receives the digital video data and a timing signal from an external system board. The timing controller 240 generates a gate control signal for controlling the operation timing of the gate driver 205 and a source control signal for controlling the source driver ICs 210 based on the timing signal. The timing controller 240 supplies the gate control signal to the gate driver 205 and the source control signal to the source driver ICs 210. For example, the gate driver 205 can supply the gate control signal to the plurality of gate lines GL according to timing control of the timing controller 240.

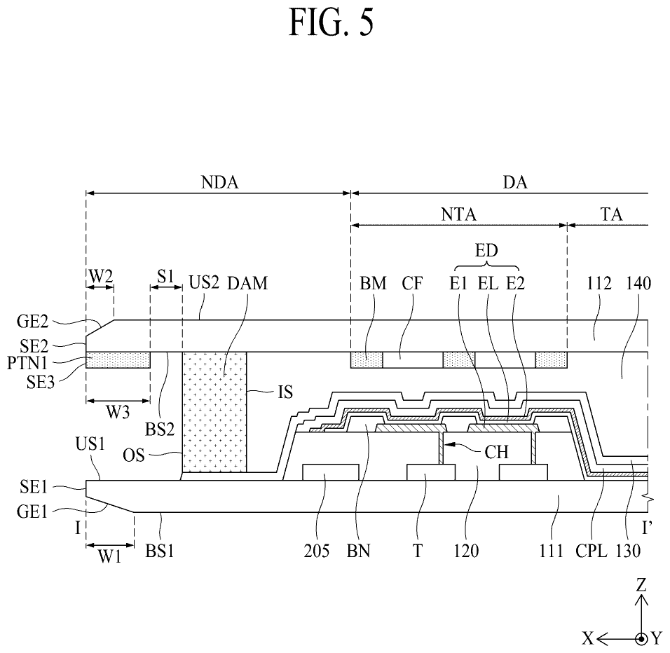

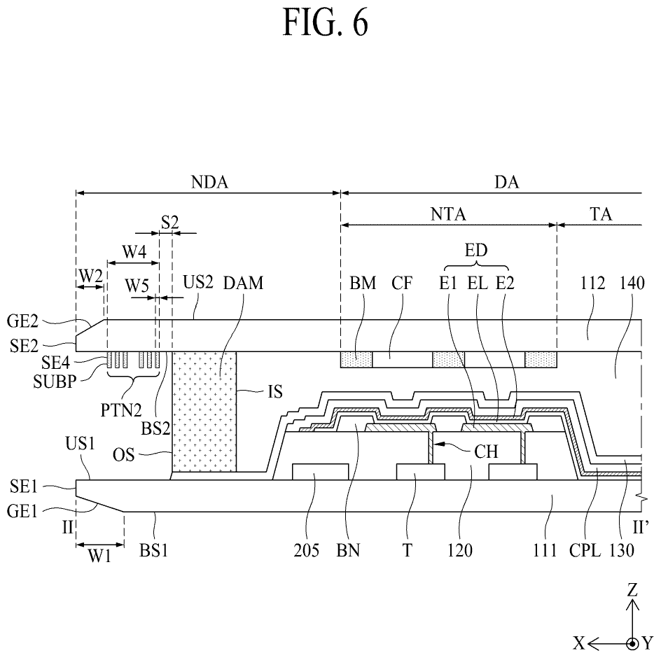

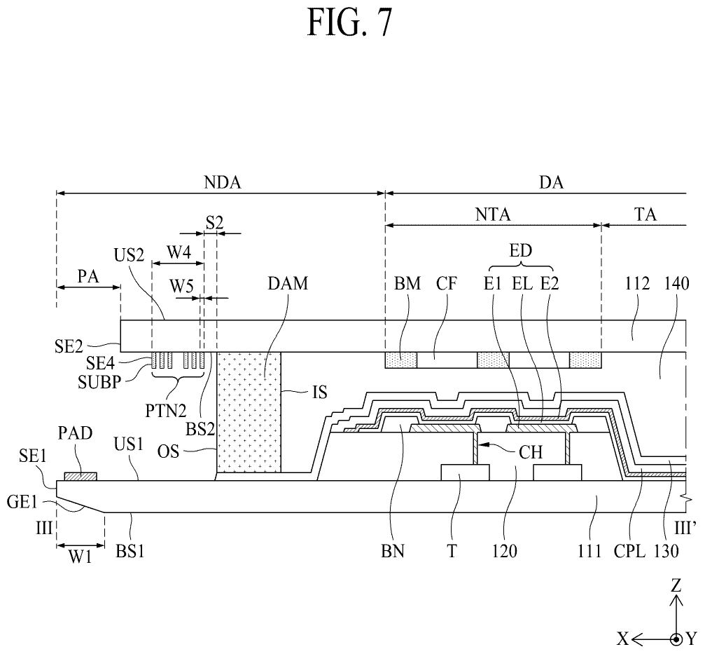

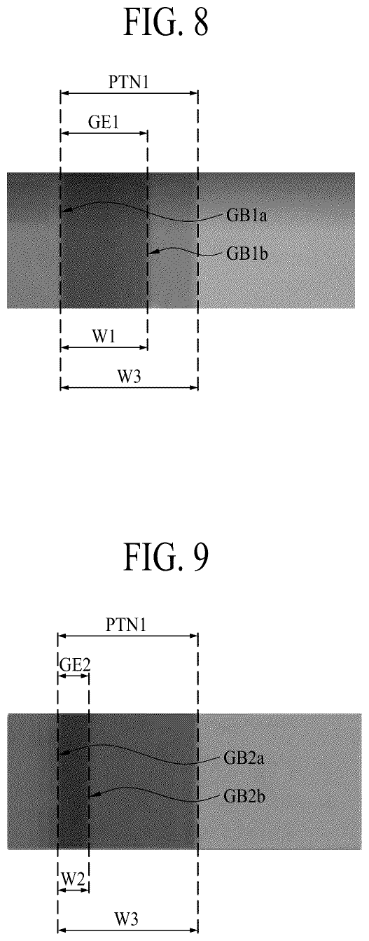

FIG. 4 is a plan view illustrating a first pattern and a second pattern disposed in the display panel according to one or more example embodiments of the present disclosure, FIG. 5 is a cross-sectional view illustrating one example taken along line I-I′ illustrated in FIG. 4, FIG. 6 is a cross-sectional view illustrating an example taken along line II-II′ illustrated in FIG. 4, FIG. 7 is a cross-sectional view illustrating an example taken along line III-III′ illustrated in FIG. 4. FIG. 8 illustrates an example of a bottom surface image acquired through a vision camera, and FIG. 9 illustrates an example of a top surface image acquired through a vision camera.

Referring to FIGS. 4 to 7, the display panel 110 according to one or more example embodiments of the present disclosure can include the display area DA and the non-display area NDA. The display area DA displays the images and the non-display area NDA does not display the images. The display area DA is provided with the pixels P that can display images.

Each of the plurality of pixels P can include a first sub-pixel SP1, a second sub-pixel SP2, a third sub-pixel SP3, and a fourth sub-pixel SP4. For example, each of the sub-pixels SP1, SP2, SP3, and SP4 can be any one of a first sub-pixel SP1 emitting red light, a second sub-pixel SP2 emitting green light, a third sub-pixel SP3 emitting blue light, and a fourth sub-pixel SP4 emitting white light, but is not limited thereto. As illustrated in FIGS. 5 to 7, each of the first to fourth sub-pixels SP1, SP2, SP3, and SP4 can be provided with a circuit element T and a light emitting device ED between the first glass substrate 111 and the second glass substrate 112. The light emitting device ED can include a first electrode E1, an organic layer EL, and a second electrode E2.

The circuit element T is disposed on the first glass substrate 111. The circuit element T can include various signal lines, thin film transistor, and capacitor, etc. The circuit element T is provided for each of the sub-pixels SP1, SP2, SP3, and SP4. The signal lines can include the gate lines for carrying gate signals (which can be referred to as scan signals), the data lines for carrying data signals (which can be referred to as data voltages or image signals), the driving power lines, the common power lines, and the reference lines, etc. The thin film transistor can include the switching thin film transistor, the driving thin film transistor, and the sensing thin film transistor.

A planarization layer 120 can be disposed on the circuit element T to planarize the step difference caused by the circuit element T. The planarization layer 120 can be disposed in the display area DA. The planarization layer 120 can be disposed in the non-transmissive area NTA and cannot be disposed in at least a portion of the transmissive area TA. The planarization layer 120 can cause refraction of light as it transmits light, thereby reducing transparency. Accordingly, the display panel 110 according to one or more example embodiments of the present disclosure can increase transparency by removing a portion of the planarization layer 120 in the transmissive area TA.

The planarization layer 120 can extend from the display area DA to a portion of the non-display area NDA. In particular, the planarization layer 120 can extend from the non-transmissive area NTA of the display area DA to a portion of the non-display area NDA. The planarization layer 120 can be formed to cover the gate driver 205 disposed in the non-display area NDA.

The planarization layer 120 can be formed of an organic insulating material such as an acrylic resin, an epoxy resin, a phenolic resin, a polyamide resin, or a polyimide resin.

The light emitting device ED and a bank BN can be disposed on the planarization layer 120. The light emitting device ED can include the first electrode E1, the organic layer EL, and the second electrode E2.

The first electrode E1 can be disposed for each of the sub-pixels SP1, SP2, SP3, and SP4 on the planarization layer 120. The first electrode E1 can be electrically connected to the circuit element T, particularly, the driving transistor DT. For example, the first electrode E1 can be electrically connected to the driving transistor DT through a contact hole CH penetrating the planarization layer 120. In detail, the first electrode E1 can be connected to one of the source electrode and the drain electrode of the driving transistor DT through a contact hole CH penetrating the planarization layer 120. The bank BN is disposed between the first electrodes E1 adjacent to each other and the first electrodes E1 adjacent to each other can be electrically insulated from each other by the bank BN.

The first electrode E1 can be formed of a highly reflective metal material such as a stacked structure of aluminum and titanium (Ti/Al/Ti), a stacked structure of aluminum and ITO (ITO/AI/ITO), an Ag alloy, a stacked structure of Ag alloy and ITO (ITO/Ag alloy/ITO), a MoTi alloy, and a stacked structure of the MoTi alloy and ITO (ITO/MoTi alloy/ITO). The Ag alloy can be an alloy such as silver Ag, palladium Pd, copper Cu, etc. The MoTi alloy can be an alloy of molybdenum Mo and titanium Ti. The first electrode E1 can be an anode electrode.

The bank BN can be disposed on the planarization layer 120. The bank BN can be formed to cover an edge of the first electrode E1 and expose a part of the first electrode E1. In particular, the bank BN can expose a part of the top surface of the first electrode E1. Accordingly, the bank BN can prevent a problem in which the light emission efficiency is deteriorated due to the concentration of current on the end of the first electrode E1.

The bank BN can define emission area of each of the subpixels SP1, SP2, SP3, and SP4. The emission area of each of the subpixels SP1, SP2, SP3, and SP4 represent areas in which the first electrode E1, the organic layer EL, and the second electrode E2 are sequentially stacked so that holes from the first electrode E1 and electrons from the second electrode E2 are coupled to each other in the organic layer EL to emit light. In this example, an area in which the bank BN is disposed does not emit light and thus becomes the non-emission area NEA, and an area in which the bank BN is not disposed and the first electrode E1 is exposed can be the emission area.

The bank BN can be made of an insulating material containing a black material. The bank BN can be made of, for example, a transparent carbon-based mixture. Specifically, the bank BN can contain carbon black, but is not limited thereto. The bank BN can also be made of a transparent insulating material.

The organic layer EL can be disposed on the first electrode E1. The organic layer EL can a hole transport layer, a light emitting layer, and an electron transport layer. In this example, when a voltage is applied to the first electrode E1 and the second electrode E2, holes and electrons move to the light emitting layer through the hole transport layer and the electron transport layer, respectively, and combines with each other in the light emitting layer to emit light.

In one or more embodiments, the organic layer EL can be a common layer commonly formed in the subpixels SP1, SP2, SP3, and SP4. In this example, the light emitting layer can be a white light emitting layer emitting white light.

In another example embodiment, the light emitting layer of organic layer EL can be formed for each of the subpixels SP1, SP2, SP3, and SP4. A first light emitting layer emitting light of a first color can be formed in the first subpixel SP1, a second light emitting layer emitting light of a second color can be formed in the second subpixel SP2, a third light emitting layer emitting light of a third color can be formed in the third subpixel SP3, and a fourth light emitting layer emitting light of a fourth color can be formed in the fourth subpixel SP4. For example, a red light emitting layer emitting red light can be formed in the first subpixel SP1, a green light emitting layer emitting green light can be formed in the second subpixel SP2, a blue light emitting layer emitting blue light can be formed in the third subpixel SP3, and a white light emitting layer emitting white light can be formed in the fourth subpixel SP4.

The second electrode E2 can be disposed on the organic layer EL and the bank BN. The second electrode E2 can be formed of a transparent metal material TCO such as ITO or IZO capable of transmitting light, or a semi-transmissive conductive material such as magnesium Mg, silver Ag, or an alloy of magnesium Mg and silver Ag. When the second electrode E2 is formed of the semi-transmissive conductive material, light emission efficiency can be increased due to a micro cavity. The second electrode E2 can be a cathode electrode.

The encapsulation layer 130 can be disposed on the light emitting devices ED. The encapsulation layer 130 can be formed on the second electrode E2 to cover the second electrode E2. The encapsulation layer 130 serves to prevent oxygen or moisture from penetrating into the organic layer EL and the second electrode E2. To this end, the encapsulation layer 130 can include at least one inorganic layer. The encapsulation layer 130 can further include at least one organic layer. In this example, the encapsulation layer 130 can have the inorganic layer on its uppermost portion. The encapsulation layer 130 can cover the display area DA and can be extended from the display area DA to a portion of the non-display area NDA. The encapsulation layer 130 can be formed to cover the planarization layer 120 and the bank BN as well as the light emitting devices ED.

The inorganic layer provided in the encapsulation layer 130 can include an inorganic insulating material. For example, the inorganic layer provided in the encapsulation layer 130 can be formed of a silicon oxide layer SiOx, a silicon nitride layer SiNx, silicon oxynitride SiOxNy and aluminum oxide, or multiple layers thereof. The organic layer provided in the encapsulation layer 130 can be formed of an organic insulating material such as an acrylic resin, an epoxy resin, a phenolic resin, a polyamide resin, or a polyimide resin.

A capping layer CPL can be further disposed between the light emitting devices ED and the encapsulation layer 130. The capping layer CPL can be disposed on the second electrode E2 to cover the second electrode E2. The capping layer CPL can improve viewing angle characteristics and increase external light emitting efficiency. The capping layer CPL can include at least one of an inorganic material and an organic material having light transmittance.

A color filter CF can be disposed on one surface of the second glass substrate 112 facing the first glass substrate 111. The color filter CF can be patterned for each of the subpixels SP1, SP2, SP3, and SP4. For example, the color filter CF can include a plurality of color filters, such as a first color filter, a second color filter, a third color filter, and a fourth color filter. The first color filter can be disposed to correspond to the first sub-pixel SP1, and can be a first color filter that transmits light of a first color, such as a red color filter that transmits red light. The second color filter can be disposed to correspond to second sub-pixel SP2, and can be a second color filter that transmits light of a second color, such as a green color filter that transmits green light. The third color filter can be disposed to correspond to the third sub-pixel SP3, and can be a third color filter that transmits light of a third color, such as a blue color filter that transmits blue light. The fourth color filter can be disposed to correspond to the fourth sub-pixel SP4, and can be a fourth color filter that transmits light of a fourth color, such as a white color filter that transmits white light. The white color filter can be made of a transparent organic material that transmits white light, but is not limited thereto.

A black matrix BM can be disposed on one surface of the second glass substrate 112 facing the first glass substrate 111. The black matrix BM can be disposed between the color filters CF. The black matrix BM can be disposed between the subpixels SP1, SP2, SP3, and SP4 to prevent color mixture from being generated between adjacent subpixels SP1, SP2, SP3, and SP4. Also, the black matrix BM can prevent light incident from the outside from being reflected by a plurality of signal lines disposed between the subpixels SP1, SP2, SP3, and SP4. The black matrix BM can include a material that absorbs light, for example, a black dye that absorbs all light in the visible wavelength band.

A filler 140 can be disposed between the first glass substrate 111 including the light emitting devices ED and the second glass substrate 112 including the color filter CF and the black matrix BM. In this example, the filler 140 can use a thermosetting resin or a UV curable resin, and can be formed of an organic material having adhesive properties. In one embodiment, the filler 140 can include a material that absorbs hydrogen.

A first pattern PTN1 can be disposed on one surface of the second glass substrate 112 facing the first glass substrate 111 in the non-display area NDA, as shown in FIG. 5. The pad area PA in which pads PAD are disposed, a dam DAM, and the first pattern PTN1 can be disposed in the non-display area NDA. In one or more embodiments, a second pattern PTN2 can be further disposed in the non-display area NDA.

The dam DAM can be disposed between the first glass substrate 111 and the second glass substrate 112 in the non-display area NDA. The dam DAM can be formed between the first glass substrate 111 and the second glass substrate 112 to be in contact with each of the first glass substrate 111 and the second glass substrate 112, and thus the first glass substrate 111 and the second glass substrate 112 can be bonded to each other. Specifically, the dam DAM can be disposed between the encapsulation layer 130 located on the first glass substrate 111 and the second glass substrate 112 in the non-display area NDA, without being limited thereto.

The dam DAM can be disposed to surround the display area DA while being spaced apart from the display area DA. The dam DAM can be disposed to be spaced apart from the edges EG1, EG2, EG3, and EG4 of the second substrate 112. That is, the dam DAM can be disposed to surround the display area DA between the edges EG1, EG2, EG3, and EG4 of the second substrate 112 and the display area DA.

The dam DAM can be spaced apart from the display area DA with the gate driver 205 interposed therebetween in the non-display area NDA. In this example, the dam DAM can be disposed not to overlap the gate driver 205 disposed in the non-display area NDA.

The dam DAM can block the flow of the filler 140 so that the filler 140 does not flow out. The dam DAM can have an inner surface IS and an outer space OS. The inner surface IS can be in contact with the filler 140. The outer surface OS can be exposed to the outside and cannot be in contact with the filler 140. The dam DAM can be made of various materials known in the art, such as a thermosetting resin or a UV curable resin.

The first pattern PTN1 can be disposed on one surface of the second glass substrate 112 facing the first glass substrate 111 in the non-display area NDA, without being limited thereto. Alternatively, the first pattern PTN1 can be disposed on one surface of the first glass substrate 111 facing the second glass substrate 112. The first pattern PTN1 is disposed outside the dam DAM in the non-display area NDA. The first pattern PTN1 is disposed outside the dam DAM. That is, the first pattern PTN1 can be disposed between the edges EG1, EG2, EG3, and EG4 of the second glass substrate 112 and the dam DAM. In this example, as shown in FIG. 5, the first pattern PTN1 can be disposed adjacent to the edges EG1, EG2, EG3, and EG4 of the second glass substrate 112 and can be spaced apart from the dam DAM.

Also, the first pattern PTN1 can be disposed to overlap at least a portion of a first grinding surface GE1 of the first glass substrate 111 and a second grinding surface GE2 of the second glass substrate 112. The first grinding surface GE1 of the first glass substrate 111 and the second grinding surface GE2 of the second glass substrate 112 disposed to face each other can be formed by grinding the first glass substrate 111 and the second glass substrate 112 using a grinder, respectively. Specifically, the first grinding surface GE1 of the first glass substrate 111 and the second grinding surface GE2 of the second glass substrate 112 can be formed by grinding the edge of the first glass substrate 111 and the edge of the second glass substrate 112 using a grinder, respectively.

Specifically, the first grinding surface GE1 of the first glass substrate 111 can be disposed at a first top surface US1, a first bottom surface BS1, and an edge of the first glass substrate 111. The first top surface US1 of the first glass substrate 111 can be a surface facing the second glass substrate 112 and can be a surface on which the light emitting devices EDs are disposed. The first bottom surface BS1 of the first glass substrate 111 can be a surface that is exposed to the outside. The first grinding surface GE1 of the first glass substrate 111 can be formed by grinding the edge of the first glass substrate 111 using the grinder. As shown in FIGS. 5 to 7, the first grinding surface GE1 of the first glass substrate 111 can be an inclined surface inclined from the first bottom surface BS1 toward the first top surface US1, but it is not limited thereto. The first grinding surface GE1 can be a curved surface according to a grinding type.

The first grinding surface GE1 can be disposed at the edge of at least one side of the first glass substrate 111. For example, the first grinding surface GE1 can be disposed at the edges of all sides of the first glass substrate 111, but it is not limited thereto.

A first edge surface SE1 can be further disposed at the edge of the first glass substrate 111. The first edge surface SE1 can be disposed between the first grinding surface GEL and the first top surface US1 to connect the first grinding surface GE1 to the first top US1. The first edge surface SE1 can be disposed at the outermost portion of the first glass substrate 111. As shown in FIGS. 5 to 7, the first edge surface SE1 can be extended vertically from the outermost portion of the top surface US1 toward the first bottom surface BS1, but it is not limited thereto. The first edge surface SE1 can be extended obliquely from the outermost portion of the first top surface US1 toward the first bottom surface BS1.

The first grinding surface GE1 can be disposed between the first edge surface SE1 and the first bottom surface BS1 to connect the first edge surface SE1 to the first bottom surface BS1. The first edge surface SE1 is not necessarily provided and can be omitted according to design rule. In this example, when the first edge surface SE1 is omitted, the first grinding surface GE1 can connect the first top surface US1 to the first bottom surface BS1 between the first top surface US1 and the first bottom surface BS1 of the first glass substrate 111.

The second grinding surface GE2 of the second glass substrate 112 can be disposed at a second top surface US2, a second bottom surface BS2, and an edge of the second glass substrate 112. Unlike the first glass substrate 111, the second top surface US2 of the second glass substrate 112 can be a surface that is exposed to the outside. The second bottom surface BS2 of the second glass substrate 112 can be faced the first glass substrate 111 and can be a surface on which a color filter CF and a black matrix BM are disposed. The second grinding surface GE2 of the second glass substrate 112 is formed by grinding the edge of the second glass substrate 112 using a grinder. As shown in FIGS. 5 to 7, the second grinding surface GE2 of the second glass substrate 112 can be an inclined surface inclined from the second top surface US2 to the second bottom surface BS2, but it is not limited thereto. The second grinding surface GE2 can be a curved surface according to a grinding type.

The second grinding surface GE2 can be disposed on the edge of at least one side of the second glass substrate 112. However, the second grinding surface GE2 cannot be disposed at an edge EG1 adjacent to the pad area PA. As shown in FIG. 4, the second glass substrate 112 can include a first edge EG1 disposed adjacent to the pad area PA, a second edge EG2 disposed to face the first edge EG1, a third edge EG3 and a fourth edge EG4 connecting the first edge EG1 and the second edge EG2. The second grinding surface GE2 can be disposed at at least one of the second to fourth edges EG2, EG3, and EG4 of the second glass substrate 112, except the first edge EG1.

The first edge EG1 of the second glass substrate 112 can be provided to expose the pads PAD disposed on the first glass substrate 111. When the first edge EG1 of the second glass substrate 112 is grinded, the exposed pads PAD can be damaged by the grinder. Thus, in order to prevent the pads PAD from being damaged, the first edge EG1 of the second glass substrate 112 cannot be grinded by the grinder. That is, the second grinding surface GE2 cannot be disposed at an edge EG1 adjacent to the pad area PA. For example, the second grinding surface GE2 can be disposed at all of the second to fourth edges EG2, EG3, and EG4 of the second glass substrate 112, but it is not limited thereto. Also, the second grinding surface GE2 can be disposed at any one of the second to fourth edges EG2, EG3, and EG4 of the second glass substrate 112, except the first edge EG1 adjacent to the pad area PA. In this case, the first pattern PTN1 can be provided at the second to fourth edges EG2, EG3, and EG4 except for the first edge EG1 of the second glass substrate 112. The first pattern PTN1 cannot be disposed between the pad area PA and the display area DA.

A second edge surface SE2 can be further disposed at the edge of the second glass substrate 112. The second edge surface SE2 can connect the second grinding surface GE2 to the second bottom surface BS2 between the second grinding surface GE2 and the second bottom surface BS2. The second edge surface SE2 can be disposed at the outermost portion of the second glass substrate 112. As shown in FIGS. 5 to 7, the second edge surface SE2 can be extended vertically from the outermost portion of the second bottom surface BS2 toward the second top surface US2, but it is not limited thereto. The second edge surface SE2 can be extended obliquely from the outermost portion of the second bottom surface BS2 toward the second top surface US2.

The second grinding surface GE2 can be disposed between the second edge surface SE2 and the second top surface US2 to connect the second edge surface SE2 and the second top surface US2. The second edge surface SE2 is not necessarily provided and can be omitted according to design rule. In this example, when the second edge surface SE2 is omitted, the second grinding surface GE2 can connect the second top surface US2 and the second bottom surface BS2 of the second glass substrate 112.

The first pattern PTN1 can be disposed on at least one surface of the first glass substrate 111 and the second glass substrate 112. The first pattern PTN1 can be disposed on one surface of the first glass substrate 111 facing the second glass substrate 112. For example, the first pattern PTN1 can be disposed on the first top surface US1 of the first glass substrate 111, and can overlap at least a portion of the first grinding surface GE1 of the first glass substrate 111. Alternatively, as shown in FIG. 5, the first pattern PTN1 can be disposed on one surface of the second glass substrate 112 facing the first glass substrate 111. For example, the first pattern PTN1 can be disposed on the second bottom surface BS2 of the second glass substrate 112, and can overlap at least a portion of the second grinding surface GE2 of the second glass substrate 112.

In one example embodiment, the first pattern PTN1 can include the same material as the black matrix BM. The first pattern PTN1 can include a material that absorbs light, such as a black matrix BM, for example, a black dye that absorbs all light in the visible wavelength band. The first pattern PTN1 can be formed through the same process as the black matrix BM. In the example embodiment in which the first pattern PTN1 is formed by the same process as the black matrix BM, a separate process for forming the first pattern PTN1 is not required, and thus the first pattern PTN1 can be formed by a simple process.

An edge of the first pattern PTN1 can be disposed at the same position on a vertical line as the second edge surface SE2 of the second glass substrate. In detail, as shown in FIG. 5, an edge surface SE3 provided at the outer edge of the first pattern PTN1 can be disposed at the same position on a vertical line as the second edge surface SE2 of the second glass substrate.

The first pattern PTN1 can be formed to have a predetermined width W3 from the same position on the vertical line as the second edge surface SE2 of the second glass substrate toward the dam DAM. The first grinding surface GE1 can be formed to have a predetermined width W1 from the same position on the vertical line as the first edge surface SE1 of the first glass substrate toward the dam DAM. The second grinding surface GE2 can be formed to have a predetermined width W2 from the same position on the vertical line as the second edge surface SE2 of the second glass substrate toward the dam DAM. In this example, the third width W3 of the first pattern PTN1 can be greater than the first width W1 of the first grinding surface GE1 of the first glass substrate 111 and the second width W2 of the second grinding surface GE2 of the second glass substrate 112. The first width W1 of the first grinding surface GE1 of the first glass substrate 111 and the second width W2 of the second grinding surface GE2 of the second glass substrate 112 can be the same or different from each other. For example, the first width W1 of the first grinding surface GE1 of the first glass substrate 111 can be greater than the second width W2 of the second grinding surface GE2 of the second glass substrate 112. In this way, even if the first width W1 of the first grinding surface GE of the first glass substrate 111 and the second width W2 of the second grinding surface GE2 of the second glass substrate 112 are different from each other, the third width W3 of the first pattern PTN1 can be greater than the second width W2 of the second grinding surface GE2 of the second glass substrate 112 as well as the first width W1 of the first grinding surface GE1 of the first glass substrate 111.

The display panel 110 according to one or more example embodiments of the present disclosure can measure the grinding amount of each of the first grinding surface GE1 of the first glass substrate 111 and the second grinding surface GE2 of the second glass substrate 112 by using the first pattern PTN1. In general, the grinding amount can be measured using a vision camera system after the grinding process. The vision camera system can capture an edge area including the first grinding surface GE1 of the first glass substrate 111 and identify a boundary of the first grinding surface GE1 of the first glass substrate 111 in the captured image. The vision camera system can measure the grinding amount based on the identified boundary of the first grinding surface GE1. For example, the vision camera system can determine the grinding amount based on the first width W1 of the first grinding surface GE1.

For example, the vision camera system can acquire a bottom surface image as shown in FIG. 8 by capturing the edge area including the first grinding surface GE1 of the first glass substrate 111 after arranging the vision camera under the display panel 110. The vision camera system can identify a boundary having a large difference in brightness in the bottom surface image as the boundary of the first grinding surface GE1. The vision camera system can identify each of a first boundary GB1a and a second boundary GB1b having a large difference in brightness in the bottom surface image as shown in FIG. 8, as the boundary of the first grinding surface GE1. Depending on a shape of the first grinding surface GE1, the first boundary GBla can be a boundary of the first glass substrate 111 as well as the boundary of the first grinding surface GE1. The vision camera system can determine the grinding amount based on the distance between the first boundary GB1a and the second boundary GB1b, that is, the first width W1 of the first grinding surface GE1.

Furthermore, the vision camera system can capture an edge area including the second grinding surface GE2 of the second glass substrate 112 and identify a boundary of the second grinding surface GE2 of the second glass substrate 112 in the captured image. The vision camera system can measure the grinding amount based on the identified boundary of the second grinding surface GE2. For example, the vision camera system can determine the grinding amount based on the second width W2 of the second grinding surface GE2.

For example, the vision camera system can acquire a top surface image as shown in FIG. 9 by capturing the edge area including the second grinding surface GE2 of the second glass substrate 112 after arranging the vision camera on the display panel 110. The vision camera system can identify a boundary having a large difference in brightness in the top surface image as the boundary of the second grinding surface GE2. The vision camera system can identify each of a first boundary GB2a and a second boundary GB2b having a large difference in brightness in the top surface image as shown in FIG. 9, as the boundary of the second grinding surface GE2. Depending on a shape of the second grinding surface GE2, the first boundary GB2a can be a boundary of the second glass substrate 112 as well as the boundary of the second grinding surface GE2. The vision camera system can determine the grinding amount based on the distance between the first boundary GB2a and the second boundary GB2b, that is, the second width W2 of the second grinding surface GE2.

In the display panel 110 according to one or more example embodiments of the present disclosure, the first pattern PTN1 can be formed to overlap the first grinding surface GE1 of the first glass substrate 111 and the second grinding surface GE2 of the second glass substrate 112, so that the boundary each of the first grinding surface GE1 of the first glass substrate 111 and the second grinding surface GE2 of the second glass substrate 112 can be more clearly displayed in the image obtained through the vision camera.

In the display panel 110 according to one or more example embodiments of the present disclosure, in order to prevent another boundary from occurring within the first grinding surface GE1 in the bottom surface image obtained through the vision camera, the first pattern PTN1 can include the third width W3 greater than the first width W1 of the first grinding surface GE1. When the first pattern PTN1 has a width less than the first width W1 of the first grinding surface GE1, within the first grinding surface GE1 in the bottom surface image obtained through the vision camera, a boundary between an area in which the first pattern PTN1 overlaps with the first grinding surface GEL and an area in which the first pattern PTN1 does not overlap with the first grinding surface GE1 can be included. Accordingly, the vision camera system can misrecognize the boundary between the area in which the first pattern PTN1 overlaps with the first grinding surface GE1 and the area in which the first pattern PTN1 does not overlap with the first grinding surface GE1 as the boundary of the first grinding surface GE1. To prevent this, the display panel 110 according to one or more example embodiments of the present disclosure can include the first pattern PTN1 having the third width W3 greater than the first width W1 of the first grinding surface GE1. Accordingly, there is no boundary within the first grinding surface GE1 in the bottom surface image acquired through the vision camera.

In the display panel 110 according to one or more example embodiments of the present disclosure, in order to prevent another boundary from occurring within the second grinding surface GE2 in the top surface image obtained through the vision camera, the first pattern PTN1 can include the third width W3 greater than the second width W2 of the second grinding surface GE2. When the first pattern PTN1 has a width less than the second width W2 of the second grinding surface GE2, within the second grinding surface GE2 in the top surface image obtained through the vision camera, a boundary between an area in which the first pattern PTN1 overlaps with the second grinding surface GE2 and an area in which the first pattern PTN1 does not overlap with the second grinding surface GE2 can be included. Accordingly, the vision camera system can misrecognize the boundary between the area in which the first pattern PTN1 overlaps with the second grinding surface GE2 and the area in which the first pattern PTN1 does not overlap with the second grinding surface GE2 as the boundary of the second grinding surface GE2. To prevent this, the display panel 110 according to one or more example embodiments of the present disclosure can include the first pattern PTN1 having the third width W3 greater than the second width W2 of the second grinding surface GE2. Accordingly, there is no boundary within the second grinding surface GE2 in the bottom surface image acquired through the vision camera.

Moreover, in the display panel 110 according to one or more example embodiments of the present disclosure, the edge surface SE3 provided at the outer edge of the first pattern PTN1 can be disposed at the same position on the vertical line with the second edge surface SE2 of the second glass substrate 112. When the edge surface SE3 of the first pattern PTN1 is disposed closer to the dam DAM than the second edge surface SE2 of the second glass substrate 112, the top surface image obtained through the vision camera can include the boundary between the area in which the second grinding surface GE2 overlaps with the first pattern PTN1 and the area in which the second grinding GE2 does not overlap with the first pattern PTN1. Accordingly, the vision camera system can misrecognize the boundary between the area in which the second grinding surface GE2 overlaps with the first pattern PTN1 and the area in which the second grinding GE2 does not overlap with the first pattern PTN1 as the boundary of the second grinding GE2. To prevent this, in the display panel 110 according to one or more example embodiments of the present disclosure, the edge surface SE3 of the first pattern PTN1 can be provided at the same position on the vertical line with the second edge surface SE2 of the second glass substrate 112. Accordingly, there is no boundary within the second grinding surface GE2 in the top surface image acquired through the vision camera.

Moreover, in the display panel 110 according to one or more example embodiments of the present disclosure, the first pattern PTN1 can be disposed to be spaced apart from the dam DAM so that the boundary of the first pattern PTN1 can be identified in an image acquired through a vision camera. When the first pattern PTN1 overlaps the dam DAM, in the image acquired through the vision camera, an area in which the first pattern PTN1 and the dam DAM are disposed can be dark and an area in which the first pattern PTN1 overlaps with the dam DAM can be relatively darker. Accordingly, the vision camera system cannot clearly identify the boundary of the first pattern PTN1 and the boundary of the dam DAM, and can misrecognize a relatively dark area, such as the area in which the first pattern PTN1 overlaps with the dam DAM, as the boundary of the first grinding surface GE1 of the first glass substrate 111 or as the boundary of the second grinding surface GE2 of the second glass substrate 112.

To prevent this, the display panel 110 according to one or more example embodiments of the present disclosure, the first pattern PTN1 can be disposed to be spaced apart from the dam DAM. In this example, in the image acquired through the vision camera, since an area in which the first pattern PTN1 and the dam DAM are spaced apart can be bright, the boundary between the first pattern PTN1 and the boundary of the dam DAM can be clearly displayed. The vision camera system can identify the boundary of the first pattern PTN1, and can identify the boundary of the first grinding surface GE1 of the first glass substrate 111 and the boundary of the second grinding surface GE2 of the second glass substrate 112 within the first pattern PTN1.

In the display panel 110 according to one or more exemplary embodiments of the present disclosure, the first pattern PTN1 can have the third width W3 greater than the first width W1 of the first grinding surface GE1, and the first pattern PTN1 can have the third width W3 greater than the second width W2 of the second grinding surface GE2. Also, in the display panel 110 according to one or more exemplary embodiments of the present disclosure, the edge surface SE3 of the first pattern PTN1 can be provided at the same position on the vertical line with the second edge surface SE2 of the second glass substrate 112. Moreover, in the display panel 110 according to one or more exemplary embodiments of the present disclosure, the first pattern PTN1 can be disposed to be spaced apart from the dam DAM. However, the present application is not limited thereto.

As a result, since the display panel 110 according to one or more example embodiments of the present disclosure includes the first pattern PTN1, the boundary of the first grinding surface GE1 of the first glass substrate 111 and the boundary of the second grinding surface GE2 of the second glass substrate 112 can be accurately identified when measuring the grinding polishing amount by the vision camera system. The display panel 110 according to one or more example embodiments of the present disclosure can reduce a misrecognition rate of the boundary of the first grinding surface GE1 of the first glass substrate 111 and the boundary of the second grinding surface GE2 of the second glass substrate 112, and further, can reduce defective processing due to misrecognition. In the display panel 110 according to one or more example embodiments of the present disclosure, since the produce defect rate decrease, the manufacturing process cost can be reduced and the manufacturing process time can be shortened, and thus the production energy can be reduced. Further, in the display panel 110 according to one or more example embodiments of the present disclosure, the generation of greenhouse gases due to the manufacturing process can be reduced, thereby implementing ESG (Environment/Social/Governance).

The first pattern PTN1 can be disposed at the edge of at least one side of the first glass substrate 111 or the second glass substrate 112. As described above, the first pattern PTN1 can be used to measure the grinding amount of the first grinding surface GE1 of the first glass substrate 111 and the second grinding surface GE2 of the second glass substrate 112, and thus can be disposed at the edge where the first grinding surface GE1 of the first glass substrate 111 and the second grinding surface GE2 of the second glass substrate 112 are formed.

As shown in FIG. 5, the first pattern PTN1 can be disposed on one surface of the second glass substrate 112, and can be provided at the edge of at least one side on which the second grinding surface GE2 is formed. For example, the second grinding surface GE2 of the second glass substrate 112 can be provided at the second to fourth edges EG2, EG3, and EG4 except for the first edge EG1 adjacent to the pad area PA, without being limited thereto. Also, the second grinding surface GE2 of the second glass substrate 112 can be disposed at any one of the second to fourth edges EG2, EG3, and EG4 of the second glass substrate 112, except the first edge EG1. In this case, the first pattern PTN1 can be provided at the second to fourth edges EG2, EG3, and EG4 except for the first edge EG1 of the second glass substrate 112. The first pattern PTN1 cannot be disposed between the pad area PA and the display area DA.

A plurality of first patterns PTN1s can be disposed to be spaced apart from each other along the edge of at least one side of the first glass substrate 111 or the second glass substrate 112. The first pattern PTN1 can be formed as a pattern having a predetermined size in an area to be captured by the vision camera. As shown in FIG. 4, the plurality of first patterns PTN1s can be disposed at edge of one side, and the plurality of first patterns PTN1s can be disposed to be spaced apart from each other. For example, the plurality of first patterns PTN1s can be disposed to be spaced apart from each other along each of the second to fourth edges EG2, EG3, and EG4 of the second glass substrate 112.

The display panel 110 according to one or more example embodiments of the present disclosure can further include a second pattern PTN2 disposed between the plurality of first patterns PTN1s.

The second pattern PTN2 can be disposed outside the dam DAM like the plurality of first patterns PTN1s to block the flow of the dam DAM so that the dam DAM does not flow to the outside or spread to an area in which the plurality of first patterns PTN1 are formed.

Like the plurality of first patterns PTN1s, a plurality of second patterns PTN2s can be disposed to be spaced apart from each other along edge of at least one side of the first glass substrate 111 or the second glass substrate 112. In this example, the plurality of first patterns PTN1s and the plurality of second patterns PTN2s can be alternately disposed along edge of at least one side of the first glass substrate 111 or the second glass substrate 112.

As an example, as illustrated in FIGS. 6 and 7, the second pattern PTN2 can be disposed on one surface of the second glass substrate 112 like the first pattern PTN1, and can be provided at edge of at least one side of the second glass substrate 112. However, the first pattern PTN1 cannot be provided at the first edge EG1 of the second glass substrate 112, but the second pattern PTN2 can be provided at the first edge EG1 of the second glass substrate 112. The second pattern PTN2 can be provided at the first to fourth edges EG1, EG2, EG3, and EG4 of the second glass substrate 112, without being limited thereto. Alternatively, the second pattern PTN2 can be provided at any one of the first to fourth edges EG1, EG2, EG3, and EG4 of the second glass substrate 112. That is, the first pattern PTN1 cannot be disposed between the pad area PA and the display area DA, but the second pattern PTN2 can be disposed between the pad area PA and the display area DA. The second pattern PTN2 can be extended long along the first edge EG1 to block the flow of the dam DAM so that the dam DAM does not spread to the pad area PA.

The second pattern PTN2 can have a fourth width W4 less than the third width W3 of the first pattern PTN1. As shown in FIGS. 6 and 7, an edge surface SE4 provided at the outer edge of the second pattern PTN2 can be positioned inwardly toward the dam DAM than the second edge surface SE2 of the second glass substrate 112. That is, the second pattern PTN2 can be formed to have a predetermined width W4 toward the dam DAM at a position more inwardly toward the dam DAM than the second edge surface SE2 of the second glass substrate 112. In this example, the fourth width W4 of the second pattern PTN2 can be less than the third width W3 of the first pattern PTN1.

In one embodiment, as illustrated in FIG. 4, the second pattern PTN2 can include a plurality of sub-patterns SUBP between two adjacent first patterns PTN1s. In this example, as illustrated in FIGS. 6 and 7, each of the plurality of sub-patterns SUBP disposed between two adjacent first patterns PTN1s has a fifth width W5 and can be spaced apart from the dam DAM in an outward direction. In the display panel 110, an uneven surface can be formed by the plurality of sub-patterns SUBP spaced apart from the dam DAM in the outward direction, and a flow of the dam DAM can be more effectively blocked by the uneven surface.

Meanwhile, the second pattern PTN2 can be disposed closer to the dam DAM than the first pattern PTN1. Specifically, the first pattern PTN1 can have a first separation distance S1 from the dam DAM. The second pattern PTN2 can have a second separation distance S2 smaller than the first separation distance S1 from the dam DAM. Accordingly, in the display panel 110 according to one or more example embodiments of the present disclosure, the flow of the dam DAM can be blocked by the second pattern PTN2 before the dam DAM is spread to the area in which the first pattern PTN1 is formed.

In one embodiment, like the first pattern PTN1, the second pattern PTN2 can include the same material as the black matrix BM. The second pattern PTN2, like the black matrix BM, can include a material that absorbs light, for example, a black dye that absorbs all light in the visible wavelength band. The second pattern PTN2 can be formed through the same process as the black matrix BM. In this example, since the first pattern PTN1 and the second pattern PTN2 can be formed by the same process as the black matrix BM, the first pattern PTN1 and the second pattern PTN2 can be formed without a separate additional process.

In one or more aspects of the present disclosure, by including a first pattern, the boundary of the grinding surface of each of the glass substrates can be clearly displayed in the image acquired through a vision camera.

Moreover, in one or more aspects of the present disclosure, it is possible to prevent the boundary of the grinding surface of each of the glass substrates from being misrecognized, thereby reducing the misrecognition rate for the boundaries of the grinding surfaces and reducing defective processing due to the misrecognition. In addition, in the present disclosure, since the produce defect rate decrease, the manufacturing process cost can be reduced and the manufacturing process time can be shortened, and thus the production energy can be reduced. Further, in the present disclosure, the generation of greenhouse gases due to the manufacturing process can be reduced, thereby implementing Environment/Social/Governance (ESG).

Moreover, in one or more aspects of the present disclosure, since the second pattern can be disposed between the first patterns, the flow of the dam can be blocked so that the dam does not flow outside or spread to an area where a plurality of first patterns are disposed.

Moreover, in one or more aspects of the present disclosure, the first pattern and the second pattern can be formed through the same process as the black matrix. Accordingly, in the present disclosure, the first pattern and the second pattern can be formed without a separate additional process.

The above-described feature, structure, and effect of the present disclosure are included in at least one embodiment of the present disclosure, but are not limited to only one embodiment. Furthermore, the feature, structure, and effect described in at least one embodiment of the present disclosure can be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure.

The various embodiments described above can be combined to provide further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display device, comprising:
a first substrate having a first grinding surface at an edge thereof;
a second substrate facing the first substrate and having a second grinding surface at an edge thereof;
a plurality of pixels disposed on one surface of the first substrate;
a display area including the plurality of pixels;
a non-display area disposed outside the display area;
a dam disposed between the first substrate and the second substrate in the non-display area; and
a first pattern disposed outside the dam.

2. The display device of claim 1, wherein the first pattern is spaced apart from the dam.

3. The display device of claim 1, wherein the first pattern overlaps with at least a portion of the first grinding surface and at least a portion of the second grinding surface.

4. The display device of claim 1, wherein the first pattern has a third width greater than each of a first width of the first grinding surface and a second width of the second grinding surface.

5. The display device of claim 4, wherein the first width of the first grinding surface is different from the second width of the second grinding surface.

6. The display device of claim 1, wherein a plurality of first patterns are disposed to be spaced apart from each other along the edge of at least one side of the first substrate or the second substrate.

7. The display device of claim 1, wherein the first pattern is disposed on one surface of the second substrate.

8. The display device of claim 7, the second substrate comprises an edge surface disposed at the edge, and
wherein the first pattern includes an edge surface disposed at a same position on a vertical line as the edge surface of the second substrate.

9. The display device of claim 1, further comprising a pad area in which a plurality of pads are disposed,
wherein the first pattern is not disposed between the display area and the pad area.

10. The display device of claim 1, further comprising a second pattern disposed outside the dam, the second pattern being disposed between adjacent first patterns.

11. The display device of claim 10, wherein the second pattern has a fourth width smaller than a third width of the first pattern.

12. The display device of claim 10, wherein the second substrate comprises an edge surface disposed at the edge, and
wherein the second pattern has an edge surface disposed at a position more inwardly toward the dam than the edge surface of the second substrate.

13. The display device of claim 10, wherein the second pattern is disposed closer to the dam than the first pattern.

14. The display device of claim 10, wherein the second pattern is disposed along the edge of at least side of the second substrate, and
wherein the second pattern is disposed to be spaced apart from the first pattern.

15. The display device of claim 10, wherein the second pattern comprises a plurality of sub-patterns disposed between adjacent first patterns.

16. The display device of claim 10, further comprising a pad area in which a plurality of pads are disposed,
wherein the second pattern is disposed between the display area and pad area.

17. The display device of claim 1, further comprising:
color filters disposed on one surface of the second substrate; and
a black matrix disposed between the color filters on the one surface of the second substrate,
wherein the first pattern is formed of a same material as the black matrix on the one surface of the second substrate.

18. The display device of claim 1, further comprising a gate driver disposed on one surface of the first substrate and disposed on at least one side of the display area,
wherein the gate driver is disposed between the dam and the display area.

19. The display device of claim 1, wherein the display area comprises an emission area provided with a plurality of light emitting devices and a transmissive area for transmitting external light.

20. The display device of claim 1, wherein the first substrate comprises a first glass substrate, and the second substrate comprises a second glass substrate.
